(19) United States
(12) Patent Application Publication
(10) Pub. No.: US 2011/0233607 A1
(43) Pub. Date: Sep. 29, 2011

(54) SEMICONDUCTOR DEVICE AND METHOD FOR MANUFACTURING SAME

(75) Inventors: Satoshi Yanagisawa, Hyogo-ken (JP); Shuji Kamata, Hyogo-ken (JP)

(73) Assignee: Kabushiki Kaisha Toshiba, Tokyo (JP)

(21) Appl. No.: 13/050,818

(22) Filed: Mar. 17, 2011

(30) Foreign Application Priority Data
Mar. 24, 2010 (JP) 2010-067572

(51) Int. Cl. H01L 29/739; H01L 21/331

(52) U.S. Cl. 257/139; 438/138; 257/E29.194; 257/E21.37

(57) ABSTRACT

According to one embodiment, a semiconductor device includes a first semiconductor layer of a first conductivity type, a first semiconductor region of a second conductivity type, a second semiconductor region of the first conductivity type, a third semiconductor region of the first conductivity type, a fourth semiconductor region of the second conductivity type, and a control electrode. The first semiconductor region is provided selectively on a first major surface of the first semiconductor layer. The second semiconductor region is provided selectively on the first major surface in contact with the first semiconductor region. The third semiconductor region is provided selectively on a surface of the first semiconductor region. The fourth semiconductor region is provided to face a projecting surface between a side surface and a bottom surface of the first semiconductor region with the second semiconductor region interposed. The control electrode is provided on the first semiconductor layer, the first semiconductor region, the second semiconductor region, and the third semiconductor region via an insulating film.

### CROSS-REFERENCE TO RELATED APPLICATIONS

This application is based upon and claims the benefit of priority from the prior Japanese Patent Application No. 2010-067572, filed on Mar. 24, 2010; the entire contents of which are incorporated herein by reference.

### FIELD

Embodiments described herein relate generally to a semiconductor device and a method for manufacturing the same.

### BACKGROUND

In recent years, there has been a strong demand for low-loss and high-performance configurations for power semiconductor devices in response to the trend toward energy efficiency. Reduction of ON resistance is an important part of a low-loss configuration for a power semiconductor device, and at the same time, enhancement of performance is required in relation to high breakdown voltage and low noise configuration. For example, a power semiconductor device that includes a field limiting ring (FLR) that is not exposed on the semiconductor surface to thereby improve breakdown voltage characteristics, and a power semiconductor device that maintains a low ON resistance and improves switching characteristics have been proposed.

However, room for improvement still remains in relation to a conventional semiconductor device, and there is a need for an enhanced-performance semiconductor device that enables maintains a low ON resistance.

### BRIEF DESCRIPTION OF THE DRAWINGS

FIGS. 1A to 1C are schematic views illustrating the structure of a semiconductor device according to a first embodiment;

FIGS. 2A and 2B are schematic views illustrating the structure of a semiconductor device according to a variation of the first embodiment;

FIGS. 3A and 3B are schematic views illustrating the structures of semiconductor devices according to a second embodiment;

FIGS. 4A and 4B are schematic views illustrating the structures of semiconductor devices according to a third embodiment;

FIG. 5 is a schematic view illustrating the structure of a semiconductor device according to a comparative example;

FIGS. 6A and 6B are schematic views illustrating the structures of semiconductor devices according to a fourth embodiment;

FIGS. 7A to 7C are cross-sectional views schematically illustrating manufacturing processes of the semiconductor device according to the fourth embodiment;

FIGS. 8A to 8C are cross-sectional views schematically illustrating the manufacturing processes subsequent to FIG. 7C;

FIG. 9 is a cross-sectional view illustrating the structure of a semiconductor device according to a fifth embodiment;

FIG. 10 is a cross-sectional view illustrating the structure of a semiconductor device according to a sixth embodiment;

FIG. 11 is a cross-sectional view schematically illustrating manufacture processes of the semiconductor device according to the sixth embodiment;

FIGS. 12A to 12C are cross-sectional views schematically illustrating the manufacturing processes subsequent to FIG. 11; and

FIGS. 13A to 13C are schematic views illustrating the structures of semiconductor devices according to a comparative example.

### DETAILED DESCRIPTION

In general, according to one embodiment, a semiconductor device includes a first semiconductor layer of a first conductivity type, a first semiconductor region of a second conductivity type, a second semiconductor region of the first conductivity type, a third semiconductor region of the first conductivity type, a fourth semiconductor region of the second conductivity type, and a control electrode. The first semiconductor region is provided selectively on a first major surface of the first semiconductor layer. The second semiconductor region is provided selectively on the first major surface in contact with the first semiconductor region. The third semiconductor region is provided selectively on a surface of the first semiconductor region. The fourth semiconductor region is provided to face a projecting surface between a side surface and a bottom surface of the first semiconductor region with the second semiconductor region interposed. The control electrode is provided on the first semiconductor layer, the first semiconductor region, the second semiconductor region, and the third semiconductor region via an insulating film.

Embodiments of the invention will now be described with reference to the drawings. In the following embodiments, the same reference numerals are used in relation to the same features, detailed description will not be repeated, and description of different features will be provided. Although an example is described in which a first conductive type is an n type, and a second conductive type is a p type, the first conductive type may be a p type and the second conductive type may be an n type.

### First Embodiment

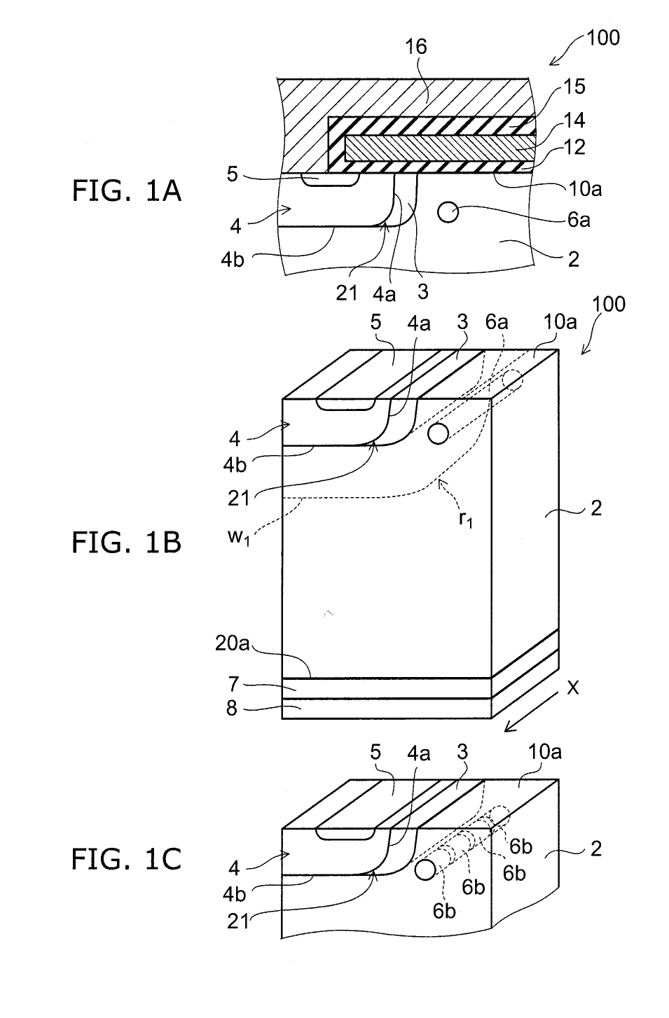

FIGS. 1A to 1C are schematic views illustrating the structure of a semiconductor device 100 according to the first embodiment. The semiconductor device 100 illustrated in the embodiment is a planar-gate insulated gate bipolar transistor (IGBT) used in applications for power control. FIG. 1A is a partial cross-sectional view illustrating the structure of the main components. FIG. 1B and FIG. 1C are perspective views illustrating the cross-sectional structure except for a gate electrode 14 and an emitter electrode 16.

The semiconductor device 100 includes an n-type base layer 2 forming a semiconductor layer of a first conductivity type, a p-type base region 4 forming a first semiconductor region of a second conductivity type, an n-type barrier region 3 forming a second semiconductor region of the first conductivity type, and an n-type emitter region 5 forming a third semiconductor region of the first conductivity type.

The p-type base region 4 is selectively provided on a major surface 10a that is a first major surface of the n-type base layer 2. The n-type barrier region 3 is in contact with a side surface 4a of the p-type base region 4 and is selectively provided on the major surface 10a. Furthermore, the n-type emitter region 5 is selectively provided on the surface of the p-type base region 4.

An n-type buffer layer 7 and a p-type collector layer 8 (second semiconductor layer) are provided on a major surface 20a (second major surface) of the n-type base layer 2. The n-type barrier region 3 that is in contact with the p-type base region 4 and selectively provided on the surface of the n-type base layer 2 has a higher carrier concentration than the n-type base layer 2.

The semiconductor device 100 further includes a p-type embedded region 6a that is a fourth semiconductor region of the second conductivity type. The p-type embedded region 6a is provided to face a projecting surface 21 between the side surface 4a and a bottom surface 4b of the p-type base region 4 with the n-type barrier region 3 interposed.

The p-type embedded region 6a can be formed by, for example, ion implantation of p-type impurities from the major surface 10a of the n-type base layer 2. In addition, after ion implantation of p-type impurities into the region forming the p-type embedded region 6a, embedding can be further executed by stacking an n-type semiconductor layer.

As illustrated in FIG. 1A, a gate electrode 14 is provided on the major surface 10a of the n-type base layer 2 via a gate insulating film 12. The gate electrode 14 is provided on a portion of the n-type emitter region 5, the p-type base region 4, the n-type barrier region 3, and the n-type base layer 2 via the gate insulating film 12. An emitter electrode 16 (main electrode) is provided above the gate electrode 14 via an interlayer insulating film 15. The emitter electrode 16 is provided so as to be in contact with the emitter region 5 and the p-type base region 4 on the major surface 10a.

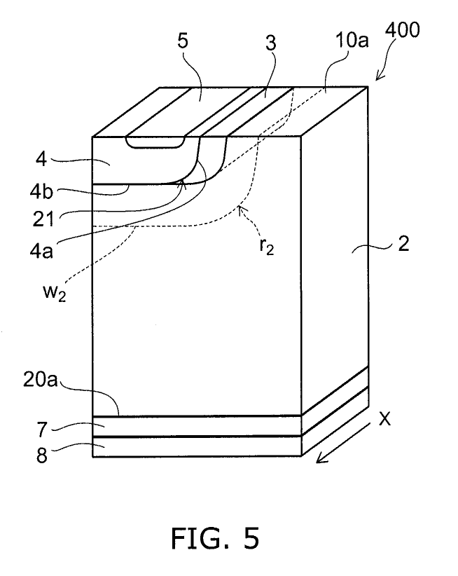

Next, operational effects of the semiconductor device 100 according to the embodiment will now be described with reference to the semiconductor device 400 according to a comparative example illustrated in FIG. 5. The semiconductor device 400 differs from the semiconductor device 100 according to the embodiment in that the p-type embedded region 6a is not provided.

The provision of the n-type barrier region 3 that has a high carrier concentration in contact with the p-type base region 4 in the semiconductor device 400 of the comparative example can suppress hole injection from the n-type base layer 2 into the p-type base region 4 and promote an effect of injection of electrons that are injected from the n-type emitter region 5 to the p-type base region 4. In this manner, the amount of electrons accumulated in the channel between the p-type base region 4 and the gate insulating film 12 is increased, and therefore, the ON resistance can be decreased.

However, the semiconductor device 400 of the comparative example is associated with the problem that the breakdown voltage is reduced when a reverse bias is applied between the n-type base layer 2 and the p-type base region 4. In other words, a depletion layer extends in a curve from the pn junction at the projecting surface 21 between the side surface 4a and the bottom surface 4b of the p-type base region 4. When its curvature is increased, the electrical field strength increases and the breakdown voltage is decreased.

For example, as illustrated in FIG. 5, a depletion layer w2 extends in the n-type base layer 2 from the p-type base region 4. The depletion layer w2 extends according to the shape of the p-type base region and has a curvature r2 that curves in a portion corresponding to the projecting surface 21. The electrical field is concentrated by the curvature in the projecting surface 21.

Furthermore, the provision of the n-type barrier region 3 that has a higher carrier concentration in contact with the p-type base region 4 suppresses an expansion in the depletion layer in the pn junction on the n-type barrier region 3 side, and therefore, the breakdown voltage is further decreased.

In contrast, the p-type embedded region 6a is provided in the semiconductor device 100 according to the embodiment in proximity to the n-type barrier region 3, which is provided to be in contact with the p-type base region 4. The p-type embedded region 6a is provided at a position and a depth such that the expansion of the depletion layer into the n-type base layer 2 is assisted and the curvature is mitigated (the curvature is reduced).

For example, the p-type embedded region 6a can be provided at a position facing the projecting surface 21 with the n-type barrier region 3 interposed in proximity to the projecting surface 21 between the side surface 4a and the bottom surface 4b of the p-type base region 4. As illustrated in FIG. 1B, expansion of the depletion layer from the projecting surface 21 can be suppressed by provision of the p-type embedded region 6a in a depletion layer w1 that expands from the p-type base region 4. The curvature r1 of the depletion layer w1 corresponding to the projecting surface 21 is mitigated. In other words, the curvature r1 of the depletion layer w1 is smaller than the curvature r2 of the depletion layer w2 illustrated in FIG. 5.

In this manner, the electrical field concentration in the projecting surface 21 can be mitigated, and a reduction in the breakdown voltage of the pn junction between the p-type base region 4 and the n-type barrier region 3 can be prevented. In other words, a semiconductor device can be realized in which the breakdown voltage is improved while an effect of promoting injection of electrons from the n-type emitter region 5 into the p-type base region 4 is maintained and the ON resistance is reduced.

As illustrated in FIG. 1B, the p-type embedded region 6a can be provided as an integrated region extending in an X direction along the outer periphery (side surface 4a) of the p-type base region 4.

Furthermore, as illustrated in FIG. 1C, multiple regions 6b separated by a suitable width in the X direction may be provided. In either configuration, a high-performance semiconductor device can be realized in which an effect of promoting injection of electrons into the p-type base region 4 is enhanced and a high breakdown voltage is ensured.

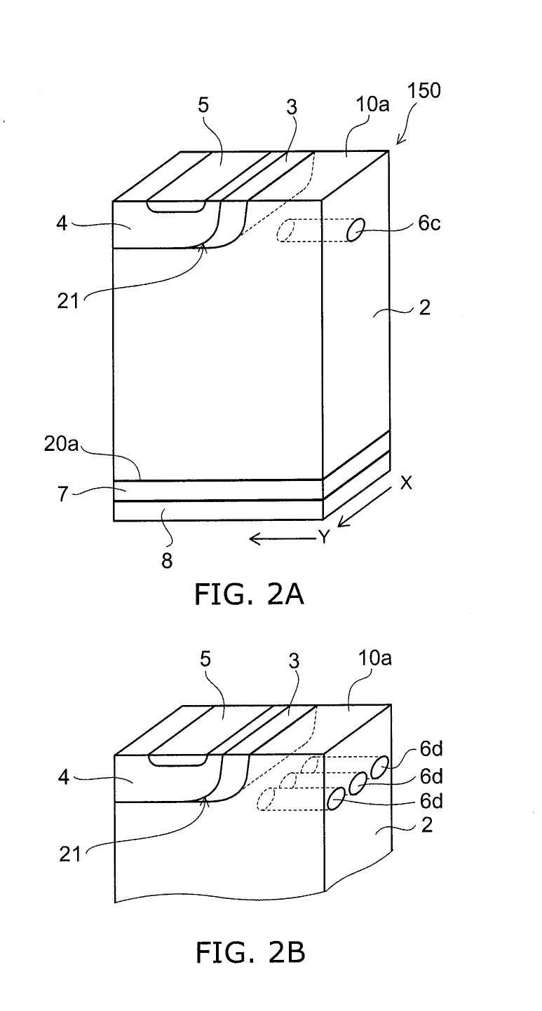

FIGS. 2A and 2B are schematic views illustrating the structure of a semiconductor device according to a variation of the first embodiment. The semiconductor device 150 differs from the semiconductor device 100 in that a p-type embedded region 6c is provided to extend in a Y direction illustrated in the figure.

An end portion of the p-type embedded region 6c is provided at a position facing the projecting surface 21 with the n-type barrier region 3 interposed in proximity to the projecting surface 21 of the p-type base region 4. As illustrated in FIG. 2B, multiple p-type embedded regions 6d may be aligned in the X direction in the figure.

In this manner, the semiconductor device 150 according to the variation can also prevent a reduction in the breakdown voltage in the pn junction between the p-type base region 4 and the n-type barrier region 3 while maintaining an effect of reducing the ON resistance.

### Second Embodiment

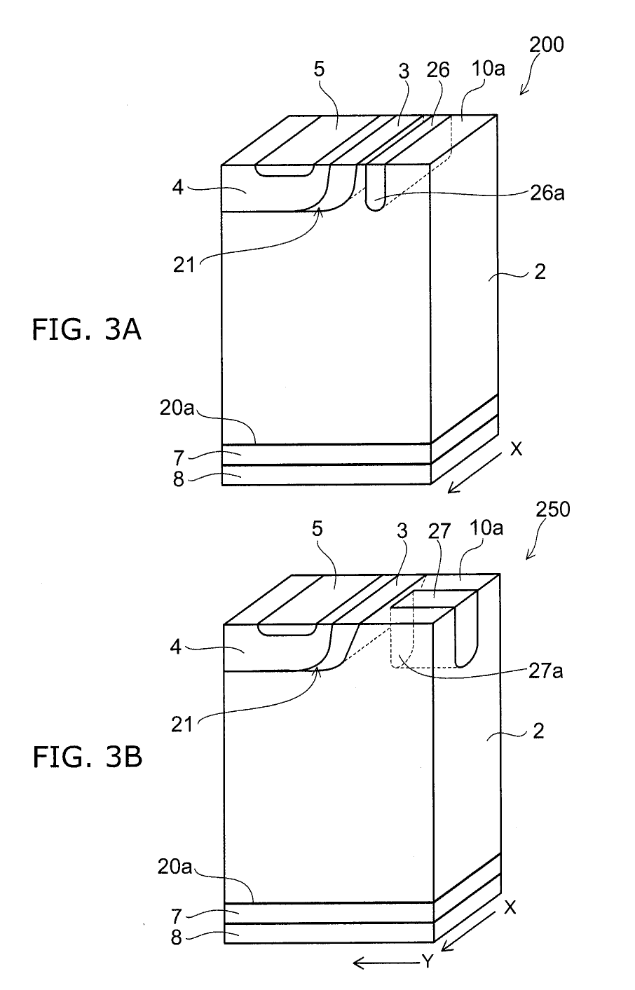

FIGS. 3A and 3B are schematic views illustrating the structures of semiconductor devices 200 and 250 according to a second embodiment. The semiconductor devices illustrated in the embodiment are also planar-gate IGBTs. FIG. 3A is a perspective view illustrating the semiconductor device 200. FIG. 3B is a perspective view illustrating the semiconductor device 250 according to a variation of the second embodiment.

In the semiconductor device 200 illustrated in FIG. 3A, a p-type embedded region 26 that is the fourth semiconductor region of the second conductivity type is provided in a direction toward the major surface 20a, that is the second major surface of the n-type base layer 2, from a position on the n-type base layer 2 side with the n-type barrier region 3 interposed in proximity to the p-type baser region 4 on the major surface 10a of the n-type base layer 2. Furthermore, an end portion 26a on the major surface 20a side of the p-type embedded region 26 is located at the depth facing the projecting surface 21 of the p-type base region 4.

The p-type embedded region 26 can be formed by, for example, ion implantation of p-type impurities from the major surface 10a side of the n-type base layer 2. Further, the n-type base layer 2 may be provided by stacking n-type semiconductor layers while repeating ion implantation of p-type impurities into the region forming the p-type embedded region 26. As described below, a trench is formed in a direction from the major surface 10a of the n-type base layer 2 to the major surface 20a, and the inner portion of the trench may be embedded by a p-type semiconductor.

The amount of p-type impurities doped into the p-type embedded region 26 may be configured with a profile in which the amount is relatively large in the end portion 26a on the major surface 20a side and the doped amount of p-type impurities decreases toward the major surface 10a.

The semiconductor device 250 illustrated in FIG. 3B includes a p-type embedded region 27 that extends in the Y direction in the figure. The p-type embedded region 27 is also provided in the direction toward the major surface 20a, that is the second major surface of the n-type base region 2, from the position on the n-type base layer 2 side with the n-type barrier region 3 interposed in proximity to the p-type baser region 4 on the major surface 10a of the n-type base layer 2. Furthermore, an end portion 27a on the major surface 20a side of the p-type embedded region 27 is located at the depth facing the projecting surface 21 of the p-type base region 4.

In the same manner as the semiconductor device 150 illustrated in FIG. 2B, multiple p-type embedded regions 27 are aligned in the X direction illustrated in FIG. 3B.

As illustrated in the above embodiment, the semiconductor devices 200 and 250 that include the p-type embedded regions 26 and 27 provided from the major surface 10a of the n-type base layer 2 toward the major surface 20a can also promote injection of electrons from the n-type emitter region to the p-type base region to maintain a low ON resistance, and improve the breakdown voltage.

### Third Embodiment

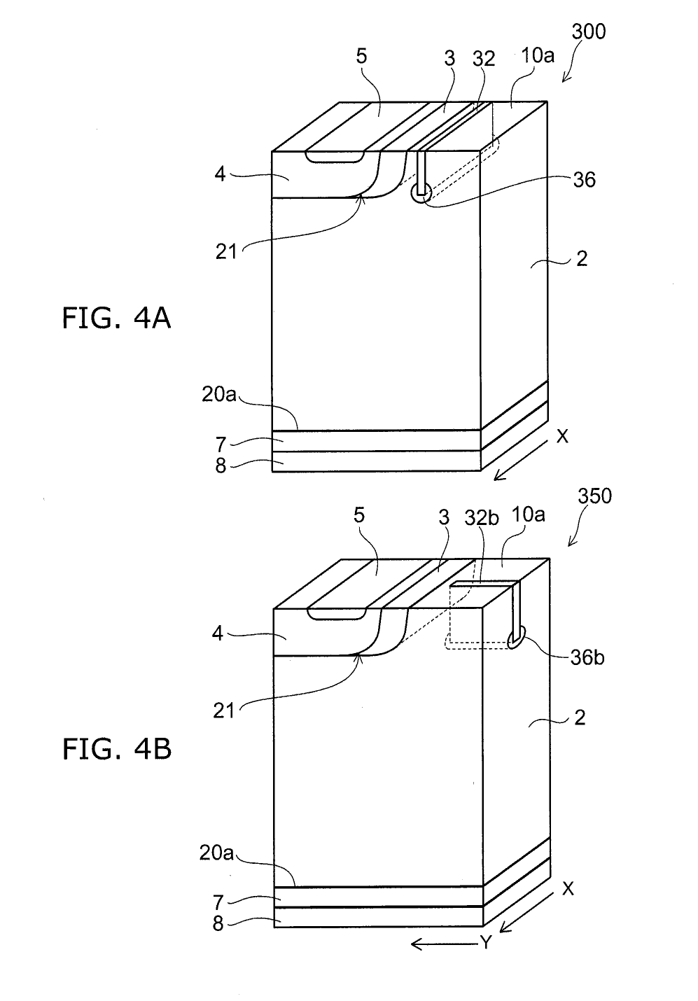

FIGS. 4A and 4B are schematic views illustrating the structures of semiconductor devices 300 and 350 according to a third embodiment. The semiconductor devices illustrated in the embodiment are also planar-gate IGBTs. FIG. 4A is a perspective view illustrating the semiconductor device 300. FIG. 4B is a perspective view illustrating the semiconductor device 350 according to a variation of the third embodiment.

The p-type embedded region 36 in the semiconductor device 300 illustrated in FIG. 4A is formed in a direction from the major surface 10a of the n-type base layer 2 toward the major surface 20a and provided at a bottom portion of a trench 32. The trench 32 is provided in a direction from the major surface on the n-type base layer 2 side with the n-type barrier region 3 interposed in proximity to the p-type base region 4 toward the major surface 20a that is the second major surface of the n-type base layer 2. Furthermore, the dimension of depth extends to the proximity of the projecting surface 21 of the p-type base region 4.

The p-type embedded region 36 may be provided by executing a process of forming the trench 32 from the first major surface 10a of the n-type base layer 2 in proximity to the p-type base region 4 with the n-type barrier region 3 interposed to the proximity of the projecting surface 21 of the p-type base region 4, and then, for example, executing a process of ion implantation of p-type impurities into the bottom portion of the trench 32.

The trench 32 may be configured by multiple trenches separated by a suitable interval in the X direction illustrated in FIG. 4A. Furthermore, the inner portion of the trench 32 may be embedded by an n-type semiconductor or may be embedded by a p-type semiconductor.

In the semiconductor device 350 illustrated in FIG. 4B, a trench 32b that extends in the Y direction illustrated in the figure is formed, and a p-type embedded region 36b is included at the bottom portion of the trench 32b. The end portion in the Y direction on the n-type barrier region 3 side of the trench 32b is formed from the major surface 10a of the n-type base layer 2 in proximity to the p-type baser region 4 with the n-type barrier region 3 interposed. The end portion also is formed with a depth that reaches to the proximity of the projecting surface 21 of the p-type base region 4. Therefore, the end portion on the n-type barrier region 3 side of the p-type embedded region 36b provided at the bottom portion of the trench 32b is located at a depth facing the projecting surface of the p-type base region 4. Multiple p-type embedded regions 36 may be aligned in the X direction illustrated in FIG. 4B.

### Fourth Embodiment

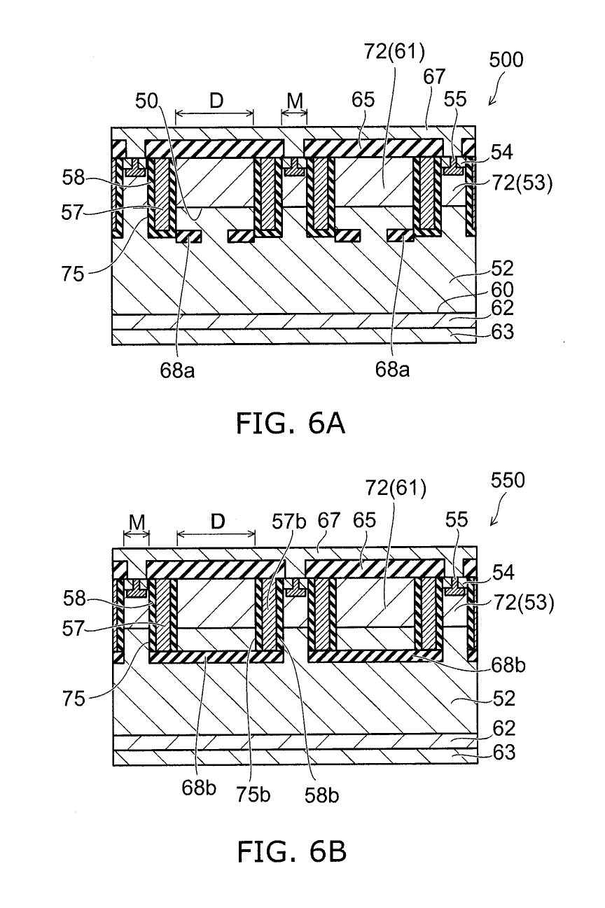

FIGS. 6A and 6B are schematic views illustrating the structures of semiconductor devices 500 and 550 according to a fourth embodiment. The semiconductor devices illustrated in the embodiment are trench-gate injection enhanced gate transistors (IEGT). The IEGT is an element capable of high breakdown voltage and large current characteristics, which the IGBT is modified, and low loss, and has a trench gate structure to further promote low loss.

FIG. 6A is a perspective view illustrating the semiconductor device 500. FIG. 6B is a perspective view illustrating the semiconductor device 550 according to a variation of the fourth embodiment.

The semiconductor device 500 illustrated in FIG. 6A includes an n-type base layer 52 that is a semiconductor layer of the first conductivity type, and a p-type base layer 72 provided on a major surface 50 that is a first major surface of the n-type base layer 52. Furthermore, in a trench 75, which is a first trench penetrating through the p-type base layer 72 from the surface of the p-type base layer to the n-type base layer 52, a gate electrode 57, which is a first gate electrode embedded via a gate insulating film 58 provided on the inner surface of the trench 75, is included.

An n-type emitter region 54 is selectively provided on the surface of the p-type base layer 72 adjacent to one side of the gate electrode 57. On the other side of the gate electrode 57, an insulating layer 68a is provided to extend in a direction along the major surface 50 of the n-type base layer 52 and to be in contact with the gate insulating film 58 at the bottom portion of the trench 75.

More specifically, the semiconductor device 500 includes a main cell M that controls current flowing from a collector electrode to an emitter electrode, and a dummy cell D provided for reducing the ON resistance of the main cell M.

The p-type base layer 72 is separated by the gate electrode 57 into a p-type base region 53 and a p-type base region 61. An n-type emitter region 54 and a p-type hole bypass 55 are selectively provided on the surface of the p-type base region 53, and thereby configure the main cell M. The p-type base region 61 is included in the dummy cell D.

An emitter electrode 67 is provided above the p-type base regions 53 and 61. The emitter region 67 is electrically connected to the emitter region 54 and the hole bypass 55 provided selectively on the surface of the p-type base region 53. An interlayer insulating film 65 is provided between the emitter electrode 67 and the p-type base region 61, and insulates the emitter electrode 67 from the p-type base region.

A n-type buffer layer 62 and a p-type collector layer 63 are provided on the major surface 60 that is the second major surface of the n-type base layer 52, and are electrically connected to the collector electrode (not illustrated).

The semiconductor device 500 may be provided on a silicon substrate, for example. The insulating layer 68a can be provided by performing ion implantation of oxygen (O+) from the surface of the silicon substrate at a predetermined depth and then performing heat treatment to form a SiO2 layer in the n-type base layer 52. Furthermore, a method may be employed in which ion implantation of O+ is performed in the region provided with the insulating layer 68a on the surface of the n-type silicon layer forming the n-type base layer 52, and n-type silicon layers are stacked to thereby form the n-type base layer 52.

In the semiconductor device 550 illustrated in FIG. 6B, a insulating layer 68b that is provided in connection with the gate electrode film 58 at the bottom portion of the trench 75 is connected between the gate electrodes 57 and 57b that partition the dummy cell D.

Next, operational effects of the semiconductor devices 500 and 550 according to the embodiment will be described.

In the semiconductor devices 500 and 550 according to the embodiment, for example, a plus voltage is applied to the collector electrode (not illustrated) that is electrically connected to the p-type collector layer 63, and the emitter electrode 67 is grounded and is placed in an operating state. In the case where the semiconductor devices 500 and 550 are in an ON state, holes are injected from the side of the p-type collector layer 63 that is subjected to the plus voltage to the n-type base layer 52. Further, the holes pass through the p-type base region 53 and the p-type hole bypass 55 of the main cell M and flow into the emitter electrode 67.

In contrast, electrons are injected from the emitter electrode 67 side through the n-type emitter region 54 into the p-type base region 53. The electrons that are injected into the p-type base region 53 pass through the channel formed in the interface between the p-type base region 53 and the gate insulating film 58, are injected into the n-type base layer 52, and flow into the p-type collector layer 63.

In the semiconductor devices 500 and 550, discharge resistance is increased in relation to holes flowing through the p-type base region 53 by reducing the width of the main cell M between the gate electrodes 57. In this manner, there is an increasing density of holes that accumulate in the n-type base region 52, and that density increase is neutralized by increasing the amount of electrons that is injected from the n-type emitter region 54 through the p-type base region 53 into the n-type base region 52. In this manner, the amount of electrons stored in the n-type base region 52 in proximity to the p-type base region 53 is increased, and the ON resistance of the channel can be reduced.

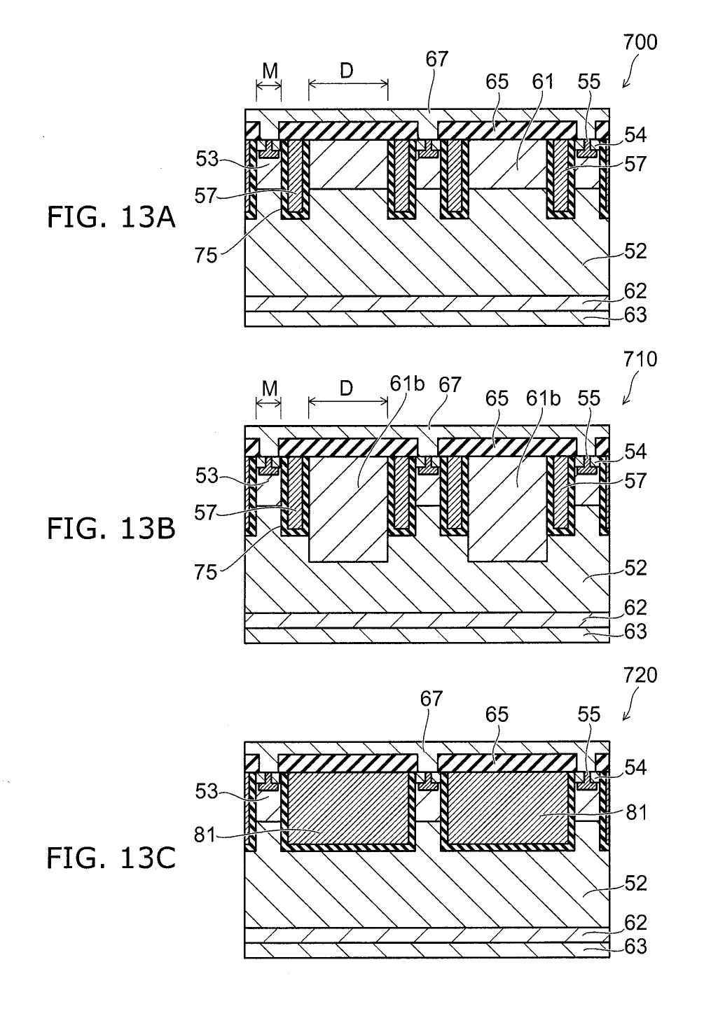

For example, in a semiconductor device 700 according to a comparative example illustrated in FIG. 13A, holes are also injected into the p-type base region 61 of the dummy cell D provided to promote electron injection and hole accumulation. The p-type base region 61 is connected through a control resistance to the emitter electrode 67 in a portion (not illustrated). The control resistance has the function of a discharge resistance for holes that flow from the p-type base region 61 to the emitter electrode 67. Since the resistance value of the control resistance is set to a value larger than the discharge resistance for holes that flow through the p-type base region 53 and the p-type hole bypass 55 of the main cell M, it is possible to maintain a high hole density in the n-type base layer 52 and promote injection of electrons from the n-type emitter region 54.

In a semiconductor device that is used for power control, there is a need to reduce switching noise caused by sharp voltage fluctuations during switching operations. Consequently, control is executed to delay the rise time and fall time of the gate voltage applied to the gate electrode 57, and thereby reducing the rate of change over time of the collector/emitter voltage (dv/dt).

However, for example, excessive accumulation of holes in the p-type base region 61 of the dummy cell D during turning ON increases the potential of the p-type base region 61, and a negative capacitance is produced between the gate and the collector. Therefore, the control of the rate of change over time of the collector/emitter voltage (dv/dt) becomes problematic.

A method to solve this problem includes a method of forming a p-type base region 61b of the dummy cell D that is deeper than the trench 75 as in a semiconductor device 710 illustrated in FIG. 13B. Furthermore as in a semiconductor device 720 illustrated in FIG. 13C, in substitution for the dummy cell D, a trench gate 81 having the same width may be provided.

In contrast, the semiconductor device 500 according to the embodiment includes an insulating layer 68a that is provided to connect to the gate insulating film 58 provided on the bottom portion of the trench 75 and extend toward the dummy cell D. In other words, in the dummy cell D enclosed by the trench 75, the embedded insulating layer 68a is partially provided at an equal depth to the trench 75 to connect with the gate insulating film 58. In this manner, the p-type base region 61 of the dummy cell D is electrically separated from the emitter electrode 67. Accordingly, injection of holes from the n-type base layer 52 to the p-type base region 61 is suppressed, and it is possible to reduce the amount of holes accumulated in the p-type base region 61.

The semiconductor device 550 illustrated in FIG. 6B further includes a gate electrode 57b that is a second gate electrode embedded via a gate insulating film 58b, that is the second gate insulating film, in a trench 75b that is the second trench separated from the trench 75 and penetrating through the base layer 72 to reach the n-type base layer 52. The insulating layer 68b is provided at the bottom portion of the trench 75 and in contact with the gate insulating film 58. The insulating layer 68b extends from the trench 75 to the trench 75b and is in contact with the gate insulating film 58b at the bottom portion of the trench 75b.

In other words, the embedded insulated film 68b, which extends between the trenches 75 and the 75b positioned on both ends of the dummy cell D and electrically separates the dummy cell D from the n-type base layer 52, is provided. In this manner, injection of holes from the n-type base layer 52 to the p-type base region 61 can be inhibited.

In the same manner as the insulating layer 68a illustrated in FIG. 6A, the insulating film 68b may be formed to connect with the gate insulating films 58 and 58b at the bottom portion of the trenches 75 and 75b, and formed as an embedded insulating film at the same width as the dummy cell D to extend in a direction along the major surface 50 of the n-type base layer 52.

The semiconductors device 500 and 550 according to the embodiment can be manufactured more easily than the semiconductor devices 710 and 720 as illustrated in FIGS. 13B and 13C, and also enable the effect of suppressing accumulation of holes in the p-type base region 61 of the dummy cell D. Therefore, superior switching characteristics can be realized in which the switching noise is reduced.

Next, a method for manufacturing the semiconductor device according to the embodiment will be described.

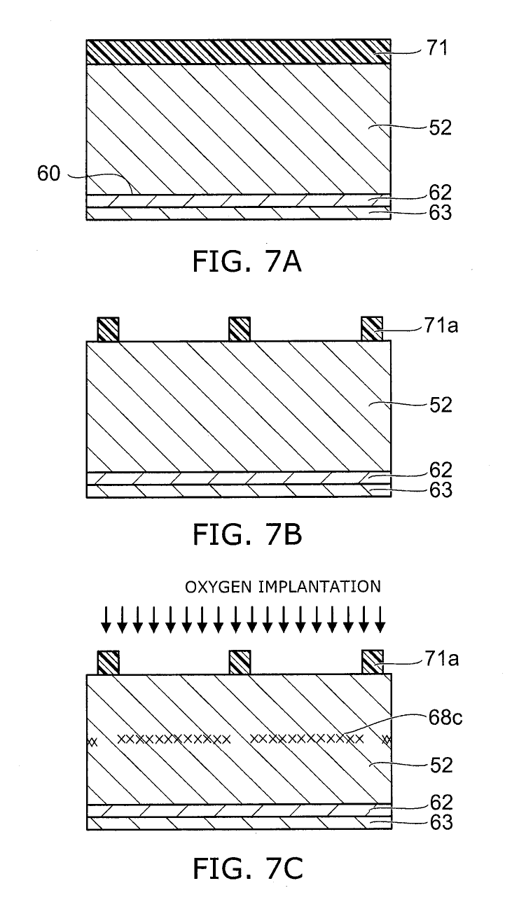

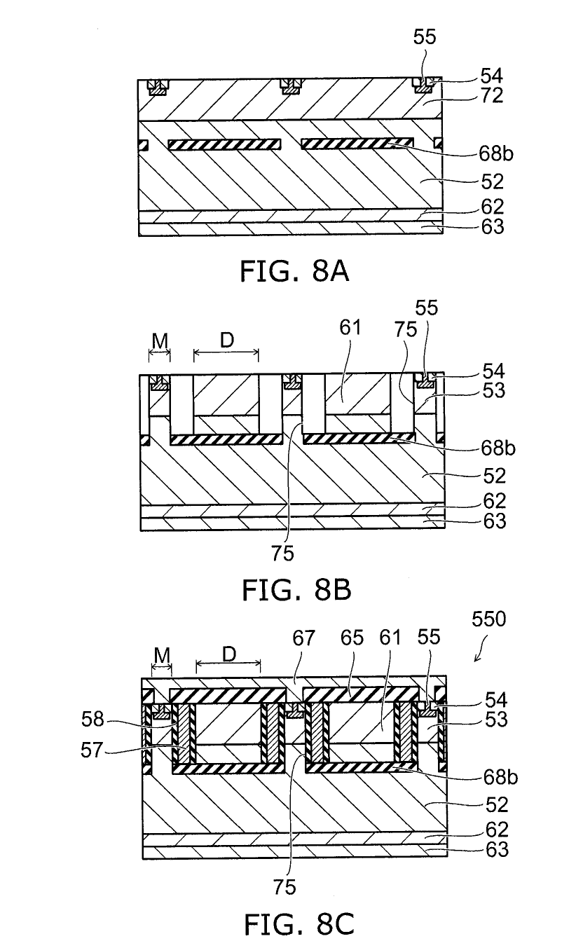

FIG. 7A to FIG. 8C are cross-sectional views schematically illustrating the manufacturing processes of the semiconductor device 550.

The method for manufacturing the semiconductor device according to the embodiment includes a process of performing ion implantation of oxygen into a region 68c forming the insulating layer 68b in the n-type base layer 52 and a process of forming the insulating layer 68b in the region in which the n-type base layer 52 is heat processed and into which oxygen is implanted.

Firstly as illustrated in FIG. 7A, an implantation mask 71 is formed on the surface of the n-type base layer 52. The ion implantation mask 71 may be a hard mask formed from a SiO2 film, for example. Furthermore, a structure may be used in which a metal layer is provided on a SiO2 film to adapt to high-energy ion implantation.

Subsequently, as illustrated in FIG. 7B, an implantation mask 71a having a predetermined opening is formed from the implantation mask 71. In this case, an opening is formed that corresponds to the region 68c provided with the insulating layer 68b.

Then, as illustrated in FIG. 7C, the implantation mask 71a is used to implant oxygen ions (O+) into the region 68c provided with the insulating layer 68b. Thereafter, the silicon substrate containing implanted O+ is heat processed, and O+ is reacted with silicon atoms to thereby form the insulating layer 68b (SiO2 layer).

Then, as illustrated in FIG. 8A, the p-type base layer 72 is formed on the surface of the n-type base layer 52 provided with the insulating layer 68b. The p-type base layer 72, for example, may be formed by ion implantation of boron (B) as a p-type impurity into the surface of the n-type base layer 52.

As illustrated in FIG. 8A, the n-type emitter region 54 and the p-type hole bypass 55 are formed selectively on the surface of the p-type base layer 72. The n-type emitter region 54, for example, may be formed by ion implantation of arsenic (As) as an n-type impurity. The p-type hole bypass 55 may be formed by ion implantation of a p-type impurity (for example, B) at a higher concentration than the p-type base layer 72.

Next, as illustrated in FIG. 8B, the trench 75 is formed to communicate from the surface of the p-type base layer 72 to the insulating layer 68b. The trench 75 forms a partition between the main cell M and the dummy cell D and separates the p-type base layer 72 into the p-type base region 53 and the p-type base region 61. Further, the gate insulating film 58 is formed by thermal oxidation of the inner surface of the trench 75.

Then, as illustrated in FIG. 8C, the gate electrode 57 is formed by embedding conductive polysilicon into an inner portion of the trench 75. The interlayer insulating film 65 is formed on the gate electrode 57 and the dummy cell D, and the emitter electrode 67 is formed on the interlayer insulating film 65 and the main cell M to thereby complete manufacture of the device structure illustrated in FIG. 6B.

### Fifth Embodiment

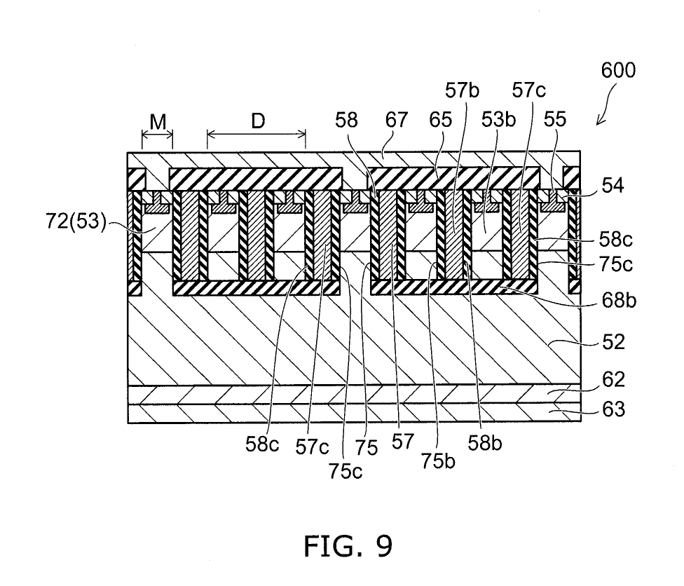

FIG. 9 is a schematic cross-sectional view illustrating the structure of a semiconductor device 600 according to a fifth embodiment. The semiconductor device 600 illustrated in the embodiment is also a trench-gate IEGT, and differs from the semiconductor device 550 illustrated in FIG. 6B in that a dummy gate 57b is provided in the dummy cell D, and an n-type emitter region 54 and p-type hole bypass 55 are provided in the p-type base region 53b of the dummy cell D.

As illustrated in FIG. 9, trenches 75, 75b, and 75c are provided at an equal interval in the semiconductor device 600 to reach the n-type base layer by piercing the p-type base layer 72. The n-type emitter region 54 and the p-type hole bypass 55 are provided on the surface of the p-type base regions 53 and 53b in which the p-type base layer 75 is divided by the respective trenches.

A central portion of the dummy cell D partitioned between the trench 75 and the trench 75c further includes a trench 75b. The gate insulating film 58 that is formed by thermally oxidizing an inner surface of the trench 75 is connected to the insulating layer 68b at a bottom portion of the trench 75. The insulating layer 68b extends from the bottom portion of the trench 75 to the bottom portions of the trench 75b and the trench 75c, and is connected to the gate insulating film 58c formed on an inner surface of the trench 75c, and the gate insulating film 58b that is formed on the inner surface of the trench 75b. In this manner, the p-type base region 53b of the dummy cell D is electrically separated from the n-type base layer 52.

Gate electrodes 57 and 57c are provided on an inner portion of the trenches 75 and 75c, and a dummy gate 57b is provided on an inner portion of the trench 75b. Furthermore, the interlayer insulating film 65 is provided to extend from an upper portion of the trench 75 to upper portions of the trench 75b and the trench 75c.

The insulating film 68b is not interposed between the trench 75 and the trench 75C that is adjacent to the trench 75. The emitter electrode 67 is connected to the n-type emitter region 54 and the p-type hole bypass 53 provided on the surface of the p-type base region 53 to thereby form a main cell M having a MOSFET structure.

This type of structure enables realization of a semiconductor device that freely varies the width of the dummy cell D and has desired characteristics. In other words, since the n-type emitter region 54 and the p-type hole bypass 55 are provided in all the p-type base regions 53 and 53b, the p-type base region that acts as the main cell M can be freely selected. Therefore, the width of the dummy cell D can be freely varied by merely varying the width provided in the insulating layer 68b and the position at which the emitter electrode 67 is in contact with the main cell M.

### Sixth Embodiment

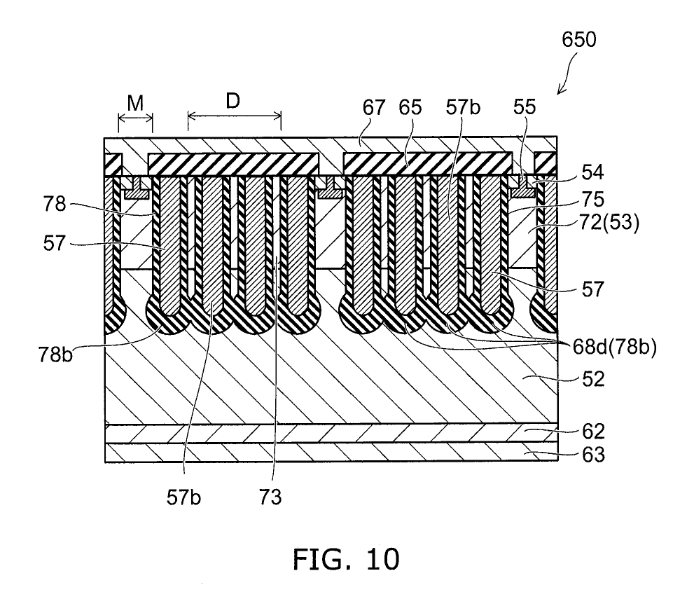

FIG. 10 is a schematic cross-sectional view illustrating the structure of a semiconductor device 650 according to a sixth embodiment. The semiconductor device 650 illustrated in the embodiment is also a trench-gate IEGT, and differs from the semiconductor device 550 illustrated in FIG. 6B in that a dummy gate 57b is provided in the dummy cell D. Furthermore, an insulating layer 68d provided in the semiconductor device 650 has a configuration in which an insulating film formed at the bottom portion of the trench 75 provided in the n-type base layer 52 is continuous.

As illustrated in FIG. 10, a thick SiO2 film 78b is formed at the bottom portion of the trench 75 of the dummy cell D, the SiO2 film 78b provided at the bottom portions of the adjacent trenches 75 forms the continuous insulating layer 68d. In this manner, the p-type base region 73 enclosed by the gate electrode 57 and the dummy gate 57b in the dummy cell D is independently electrically separated. This structure can obtain superior switching characteristics in the same manner as the semiconductor device 550 illustrated in FIG. 6B or the semiconductor device 720 illustrated in FIG. 13C.

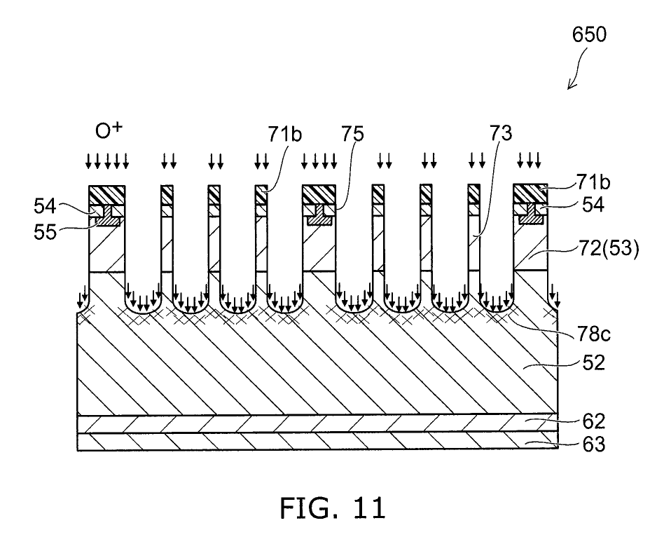

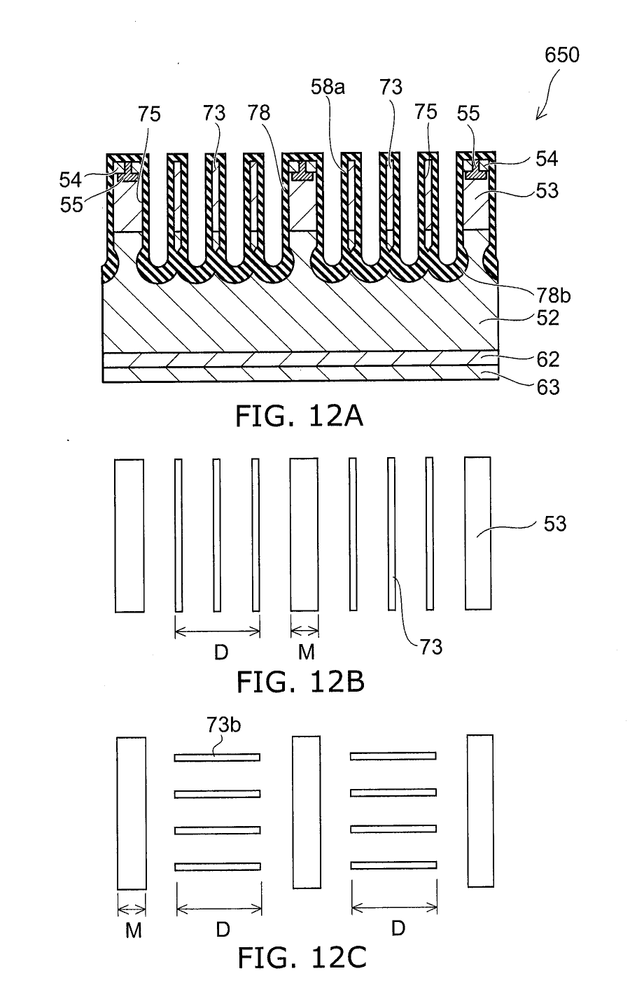

FIG. 11 to FIG. 12C are cross-sectional view schematically illustrating the manufacture process of the semiconductor device 650.

The manufacture method according to the embodiment as illustrated in FIG. 11 forms a trench 75 from the surface of the p-type base surface 72 (refer to FIG. 8A) to the n-type base layer 52.

For example, the trench 75 reaching the n-type base layer 52 is formed by a reactive ion etching (RIE) method using an etching mask 71b formed from a SiO2 film. At this time, the width of a portion of the dummy cell D that forms the p-type base region 73 is formed narrowly so that the SiO2 films 78b formed at the bottom portions 78c of the trenches 75 are mutually connected.

Next, oxygen ions (O+) are implanted into the bottom portion 78c of the trench 75. At this time, the acceleration energy of implanting ions is set with the interval between the trenches 75 considered so that the distribution of the oxygen ions introduced into the bottom portion 78c overlaps with the adjacent trench gate in the dummy cell D.

As illustrated in FIG. 12A, by performing a heat treatment in an oxygen atmosphere, the SiO2 film 78b can be formed at the bottom portion of the trench 75 and the gate insulating film 78 can be formed on the side surface of the trench 75. The SiO2 films 78b are connected to thereby form the insulating layer 68d.

FIGS. 12B and 12C are schematic views illustrating the planar disposition of the p-type base region 53 of the main cell M and the p-type base region 73 of the dummy cell D.

For example, as illustrated in FIG. 12B, the p-type base region 73 disposed in the dummy cell D can be provided in parallel with the p-type base region 53 formed in a striped configuration. Furthermore, as illustrated in FIG. 12C, the p-type base region 73 disposed in the dummy cell D may be provided in a direction orthogonal to the p-type base region 53 formed in a striped configuration.

Next, the gate electrode 57 and the dummy gate 75b are formed by embedding conductive polysilicon in an inner portion of the trench 75 as illustrated in FIG. 12A. The interlayer insulating film 65 and the emitter electrode 67 are formed to thereby complete manufacture of the semiconductor device 650 as illustrated in FIG. 10.

Although the invention has been described with reference to the first to the sixth embodiments, the invention is not limited to the embodiments. For example, embodiments that are the same as the technical concept of the invention are included within the technical scope of the invention by variation of material, variation of design by a person of ordinary skill in the art based on the technical level at the time of application.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first semiconductor layer of a first conductivity type;
a first semiconductor region of a second conductivity type provided selectively on a first major surface of the first semiconductor layer;
a second semiconductor region of the first conductivity type provided selectively on the first major surface in contact with the first semiconductor region;
a third semiconductor region of the first conductivity type provided selectively on a surface of the first semiconductor region;
a fourth semiconductor region of the second conductivity type provided to face a projecting surface between a side surface and a bottom surface of the first semiconductor region with the second semiconductor region interposed; and
a control electrode provided on the first semiconductor layer, the first semiconductor region, the second semiconductor region, and the third semiconductor region via an insulating film.

2. The device according to claim 1, further comprising:
a main electrode being in contact with the first semiconductor region and the third semiconductor region; and
a second semiconductor layer of the second conductivity type provided on a second major surface side of the first semiconductor layer.

3. The device according to claim 1, wherein a carrier concentration of the third semiconductor region is higher than a carrier concentration of the first semiconductor layer.

4. The device according to claim 1, wherein the fourth semiconductor region is provided in a portion facing the projecting surface in the first semiconductor layer.

5. The device according to claim 4, wherein the fourth semiconductor region extends along the side surface of the first semiconductor region.

6. The device according to claim 4, wherein a plurality of the fourth semiconductor regions are separated from each other and provided in a direction along the side surface of the first semiconductor region.

7. The device according to claim 4, wherein the fourth semiconductor region extends in a direction intersecting with the side surface of the first semiconductor region.

8. The device according to claim 7, wherein a plurality of the fourth semiconductor regions are separated from each other and provided in a direction along the side surface of the first semiconductor region.

9. The device according to claim 1, wherein the fourth semiconductor region is provided in a direction from the first major surface of the first semiconductor layer toward a second major surface of the first semiconductor layer, and an end portion on the second major surface side faces the projecting surface.

10. The device according to claim 9, wherein the fourth semiconductor region extends along the side surface of the first semiconductor region.

11. The device according to claim 9, wherein the fourth semiconductor region extends in a direction intersecting with the side surface of the first semiconductor region.

12. The device according to claim 11, wherein a plurality of the fourth semiconductor regions are separated from each other and provided in a direction along the side surface of the first semiconductor region.

13. The device according to claim 9, wherein an impurity concentration of the end portion on the second major surface side in the fourth semiconductor region is higher than an impurity concentration of a portion on the first major surface side.

14. The device according to claim 1, wherein the fourth semiconductor region faces the projecting surface provided at a bottom portion of a trench formed in a direction from the first major surface of the first semiconductor layer toward a second major surface of the first semiconductor layer.

15. The device according to claim 14, wherein
the trench is formed along the side surface of the first semiconductor region, and
the fourth semiconductor region extends along the bottom portion of the trench.

16. The device according to claim 14, wherein
the trench is provided to extend in a direction intersecting with the side surface of the first semiconductor region, and
the fourth semiconductor region faces the projecting surface at an end of the trench on the first semiconductor region side.

17. The device according to claim 16, wherein a plurality of the fourth semiconductor regions are separated from each other and provided in a direction along the side surface of the first semiconductor region.

18. The device according to claim 14, wherein an n-type semiconductor layer or a p-type semiconductor layer is provided in an inner portion of the trench.

19. A method for manufacturing a semiconductor device, the device including: a first semiconductor layer of a first conductivity type; a first semiconductor region of a second conductivity type provided selectively on a first major surface of the first semiconductor layer; a second semiconductor region of the first conductivity type provided selectively on the first major surface in contact with the first semiconductor region; a third semiconductor region of the first conductivity type provided selectively on a surface of the first semiconductor region; and a control electrode provided on the first semiconductor layer, the first semiconductor region, the second semiconductor region, and the third semiconductor region via an insulating film, the method comprising:
forming a trench from the first major surface of the first semiconductor layer to a proximity of a projecting surface between a side surface and a bottom surface of the first semiconductor region; and
performing ion implantation of an impurity of the second conductivity type into a bottom portion of the trench.

20. The method according to claim 19, further comprising embedding the trench with a semiconductor of the first conductivity type or the second conductivity type.
